(19) United States
(12) Patent Application Publication
(10) Pub. No.: US 2024/0113685 A1
(43) Pub. Date: Apr. 4, 2024

(54) ACOUSTIC WAVE RESONATOR BACK END SILICON DIOXIDE VIA FORMATION

(71) Applicant: SKYWORKS SOLUTIONS, INC., Irvine, CA (US)

(72) Inventors: Yiliu Wang, Irvine, CA (US); Tomoya Komatsu, Irvine, CA (US); Nan Wu, Irvine, CA (US); Atsushi Takano, Kadoma-Shi (JP)

(73) Assignee: SKYWORKS SOLUTIONS, INC., Irvine, CA (US)

(21) Appl. No.: 18/372,817

(22) Filed: Sep. 26, 2023

Related U.S. Application Data
(60) Provisional application No. 63/378,305, filed on Oct. 4, 2022.

(51) Int. Cl. H03H 9/17; H03H 3/02

(52) U.S. Cl. CPC H03H 9/174; H03H 3/02; H03H 2003/023

(57) ABSTRACT

A method of fabricating an acoustic wave resonator includes forming a dielectric layer on an upper surface of a substrate, forming a lower electrode on an upper surface of the dielectric layer, forming a layer of piezoelectric material on an upper surface of the lower electrode, forming a dielectric material layer via in the dielectric layer subsequent to forming the lower electrode and the layer of piezoelectric material, and forming a conductive through substrate via passing through the substrate and the dielectric material layer via and contacting a lower surface of the lower electrode.

### CROSS-REFERENCE TO RELATED APPLICATIONS

This application claims priority under 35 U.S.C. § 119(e) to U.S. Provisional Patent Application Ser. No. 63/378,305 titled “ACOUSTIC WAVE RESONATOR BACK END SILICON DIOXIDE VIA FORMATION,” filed Oct. 4, 2022, the entire content of which is incorporated herein by reference for all purposes.

### BACKGROUND

### Technical Field

Embodiments of this disclosure relate to acoustic wave devices, specifically bulk acoustic wave resonators and electronic devices and modules including same.

### Description of Related Technology

Acoustic wave devices, for example, bulk acoustic wave (BAW) devices may be utilized as components of filters in radio frequency electronic systems. For instance, filters in a radio frequency front end of a mobile phone can include acoustic wave filters. Two acoustic wave filters can be arranged as a duplexer.

### SUMMARY

In accordance with one aspect, there is provided a method of fabricating an acoustic wave resonator. The method comprises forming a dielectric layer on an upper surface of a substrate, forming a lower electrode on an upper surface of the dielectric layer, forming a layer of piezoelectric material on an upper surface of the lower electrode, forming a dielectric material layer via in the dielectric layer subsequent to forming the lower electrode and the layer of piezoelectric material, and forming a conductive through substrate via passing through the substrate and the dielectric material layer via and contacting a lower surface of the lower electrode.

In some embodiments, the dielectric material layer via is formed in a back end portion of a manufacturing process for the acoustic wave resonator.

In some embodiments, the method further comprises forming an upper electrode on an upper surface of the layer of piezoelectric material, forming a second dielectric material layer via in the dielectric layer subsequent to forming the upper electrode, and forming a second conductive through substrate via passing through the substrate and the dielectric material layer via and contacting a lower surface of the upper electrode.

In some embodiments, the method further comprises forming an adhesion layer on the upper surface of the dielectric layer prior to forming the lower electrode on the upper surface of the dielectric layer.

In some embodiments, contacting the lower surface of the lower electrode with the conductive through substrate via includes contacting the lower surface of the lower electrode with the conductive through substrate via at a position substantially coplanar with an upper surface of the dielectric layer.

In some embodiments, contacting the lower surface of the lower electrode with the conductive through substrate via includes contacting the lower surface of the lower electrode with the conductive through substrate via at a position proximate an upper surface of the dielectric layer.

In some embodiments, contacting the lower surface of the lower electrode with the conductive through substrate via includes contacting the lower surface of the lower electrode with the conductive through substrate via at a position coplanar with an upper surface of the adhesion layer.

In some embodiments, contacting the lower surface of the lower electrode with the conductive through substrate via includes contacting the lower surface of the lower electrode with the conductive through substrate via at a position coplanar with an upper surface of the dielectric layer.

In some embodiments, the conductive through substrate via is formed with a same width as a width of the dielectric material layer via.

In some embodiments, contacting the lower surface of the lower electrode with the conductive through substrate via includes contacting the lower surface of the lower electrode with the conductive through substrate via at a position distal from a lower surface of the dielectric layer.

In some embodiments, the dielectric material layer via is not formed in a front end portion of a manufacturing process for the acoustic wave resonator.

In accordance with another aspect, there is provided a bulk acoustic wave resonator. The bulk acoustic wave resonator comprises a dielectric layer disposed on an upper surface of a substrate, a lower electrode disposed on an upper surface of the dielectric layer, a layer of piezoelectric material disposed on an upper surface of the lower electrode, a dielectric material layer via defined in the dielectric layer, and a conductive through substrate via passing through the substrate and the dielectric material layer via and contacting a lower surface of the lower electrode at a position proximate an upper surface of the dielectric material layer.

In some embodiments, the bulk acoustic wave resonator further comprises an upper electrode disposed on an upper surface of the layer of piezoelectric material, a second dielectric material layer via defined in the dielectric layer, and a second conductive through substrate via passing through the substrate and the dielectric material layer via and contacting a lower surface of the upper electrode a position proximate an upper surface of the dielectric material layer.

In some embodiments, the bulk acoustic wave resonator further comprises an adhesion layer disposed between the upper surface of the dielectric layer and the lower electrode.

In some embodiments, the lower surface of the lower electrode contacts the conductive through substrate via at a position substantially coplanar with an upper surface of the dielectric layer.

In some embodiments, the lower surface of the lower electrode contacts the conductive through substrate via at a position proximate an upper surface of the dielectric layer.

In some embodiments, the lower surface of the lower electrode contacts the conductive through substrate at a position coplanar with an upper surface of the adhesion layer.

In some embodiments, the lower surface of the lower electrode contacts the conductive through substrate via at a position coplanar with an upper surface of the dielectric layer.

In some embodiments, the conductive through substrate via is has a same width as a width of the dielectric material layer via.

In some embodiments, the lower surface of the lower electrode contacts the conductive through substrate via at a position distal from a lower surface of the dielectric layer.

### BRIEF DESCRIPTION OF THE DRAWINGS

Embodiments of this disclosure will now be described, by way of non-limiting example, with reference to the accompanying drawings.

FIG. 1A is a simplified cross-sectional diagram of an example of a film bulk acoustic wave resonator (FBAR);

FIG. 1B is a simplified cross-sectional diagram of another example of a FBAR;

FIGS. 2A-2D illustrate steps in an example of a front end of a manufacturing process for a FBAR;

FIG. 3A is a simplified circuit schematic of an example of a ladder filter;

FIG. 3B is a simplified circuit schematic of another example of a ladder filter;

FIG. 4A illustrates one example of a connection between a through-substrate via and a lower electrode in a FBAR;

FIG. 4B illustrates another example of a connection between a through-substrate via and a lower electrode in a FBAR;

FIG. 5A illustrates another example of a connection between a through-substrate via and a lower electrode in a FBAR;

FIG. 5B illustrates another example of a connection between a through-substrate via and a lower electrode in a FBAR;

FIG. 6 a block diagram illustrating one example of an electronics module including a BAW filter;

FIG. 7 is a block diagram of one example of a front-end module; and

FIG. 8 is a block diagram of one example of a wireless device.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale and that some intermediate materials or layers are not illustrated. Moreover, it will be understood that certain embodiments can include more elements than illustrated in a drawing and/or a subset of the elements illustrated in a drawing. Further, some embodiments can incorporate any suitable combination of features from two or more drawings.

Film bulk acoustic wave resonators (FBARs) are a form of bulk acoustic wave (BAW) resonator that generally includes a film of piezoelectric material sandwiched between a top and a bottom electrode and suspended over a cavity that allows for the film of piezoelectric material to vibrate. A signal applied across the top and bottom electrodes causes an acoustic wave to be generated in and travel through the film of piezoelectric material. A FBAR exhibits a frequency response to applied signals with a resonance peak determined by a thickness of the film of piezoelectric material. Ideally, the only acoustic wave that would be generated in a FBAR is a main acoustic wave that would travel through the film of piezoelectric material in a direction perpendicular to layers of conducting material forming the top and bottom electrodes, sometimes referred to as “piston mode” operation. The piezoelectric material of a FBAR, however, typically has a non-zero Poisson's ratio. Compression and relaxation of the piezoelectric material associated with passage of the main acoustic wave may thus cause compression and relaxation of the piezoelectric material in a direction perpendicular to the direction of propagation of the main acoustic wave. The compression and relaxation of the piezoelectric material in the direction perpendicular to the direction of propagation of the main acoustic wave may generate transverse acoustic waves that travel perpendicular to the main acoustic wave (parallel to the surfaces of the electrode films) through the piezoelectric material. The transverse acoustic waves may be reflected back into an area in which the main acoustic wave propagates and may induce spurious acoustic waves travelling in the same direction as the main acoustic wave. These spurious acoustic waves may degrade the frequency response of the FBAR from what is expected or from what is intended and are generally considered undesirable.

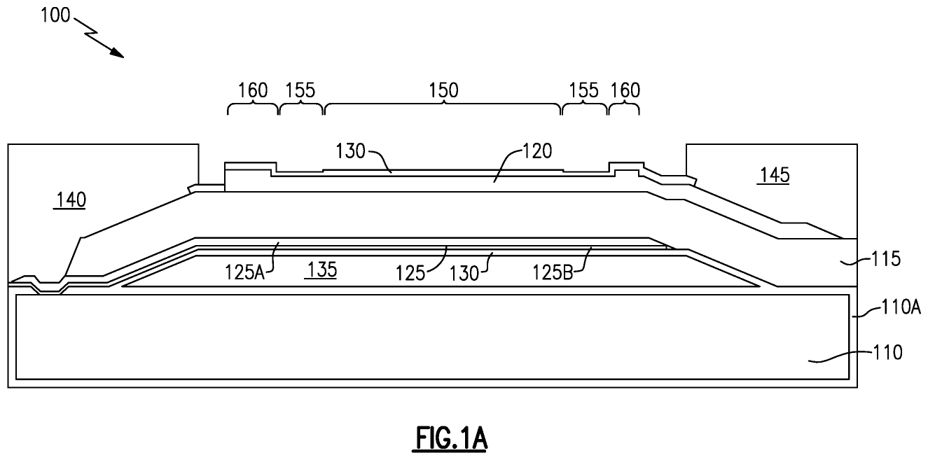

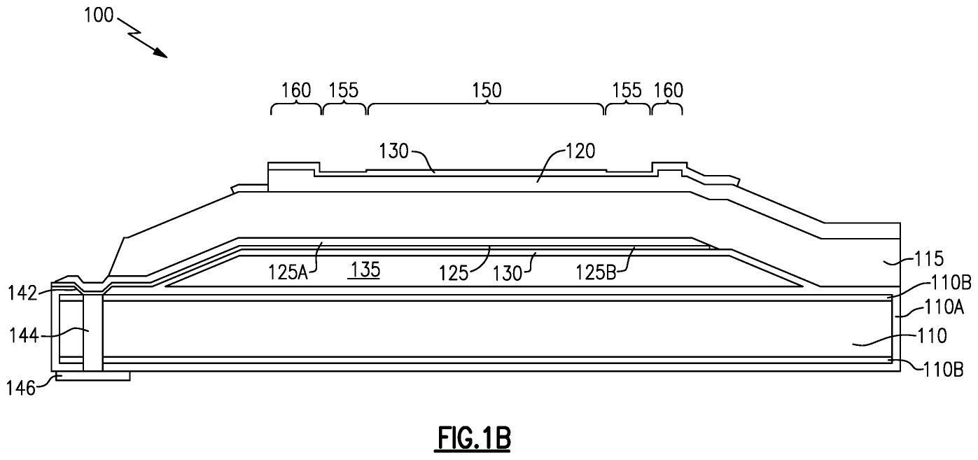

FIG. 1A is cross-sectional view of an example of a FBAR, indicated generally at 100, having what may be referred to as a mesa structure. The FBAR 100 is disposed on a substrate 110, for example, a silicon substrate that may include a dielectric layer 110A of, for example, silicon dioxide. In some embodiments a trap rich layer of silicon or polysilicon 110B is disposed on or within the upper (or upper and lower) surface of the substrate 110 between the interior bulk of the substrate 110 and the dielectric layer 110A. (See FIG. 1B) The FBAR 100 includes a layer or film of piezoelectric material 115, for example, aluminum nitride (AlN). A top electrode 120 is disposed on top of a portion of the layer or film of piezoelectric material 115 and a bottom electrode 125 is disposed on the bottom of a portion of the layer or film of piezoelectric material 115. The top electrode 120 may be formed of, for example, ruthenium (Ru), molybdenum (Mo), or a Ru/Mo alloy. The bottom electrode 125 may include a layer 125A of Ru (or Mo or Ru/Mo alloy) disposed in contact with the bottom of the portion of the layer or film of piezoelectric material 115 and a layer 125B of titanium (Ti) disposed on a lower side of the layer 125A of Ru opposite a side of the layer 125A of Ru in contact with the bottom of the portion of the layer or film of piezoelectric material 115. Each of the top electrode 120 and the bottom electrode 125 may be covered with a layer of dielectric material 130, for example, silicon dioxide. A cavity 135 is defined beneath the layer of dielectric material 130 covering the bottom electrode 125 and the dielectric layer 110A of the substrate 110. A bottom electrical contact 140 formed of, for example, copper may make electrical connection with the bottom electrode 125 and a top electrical contact 145 formed of, for example, copper may make electrical connection with the top electrode 120.

The FBAR 100 may include a central region 150 including a main active domain in the layer or film of piezoelectric material 115 in which a main acoustic wave is excited during operation. The central region 150 may also be referred to as the active area of the FBAR 100. The central region may have a width of, for example, between about 20 μm and about 100 μm. A recessed frame region or regions 155 may bound and define the lateral extent of the central region 150. The recessed frame regions may have a width of, for example, about 1 μm. The recessed frame region(s) 155 may be defined by areas that have a thinner layer of dielectric material 130 on top of the top electrode 120 than in the central region 150. The dielectric material layer 130 in the recessed frame region(s) 155 may be from about 10 nm to about 100 nm thinner than the dielectric material layer 130 in the central region 150. The difference in thickness of the dielectric material in the recessed frame region(s) 155 vs. in the central region 150 may cause the resonant frequency of the device in the recessed frame region(s) 155 to be between about 5 MHz to about 50 MHz higher than the resonant frequency of the device in the central region 150. In some embodiments, the thickness of the dielectric material layer 130 in the central region 150 may be about 200 nm to about 300 nm and the thickness of the dielectric material layer 130 in the recessed frame region(s) 155 may be about 100 nm. The dielectric film 300 in the recessed frame region(s) 155 is typically etched during manufacturing to achieve a desired difference in acoustic velocity between the central region 150 and the recessed frame region(s) 155. Accordingly, the dielectric film 300 initially deposited in both the central region 150 and recessed frame region(s) 155 is deposited with a sufficient thickness that allows for etching of sufficient dielectric film 300 in the recessed frame region(s) 155 to achieve a desired difference in thickness of the dielectric film 300 in the central region 150 and recessed frame region(s) 155 to achieve a desired acoustic velocity difference between these regions.

A raised frame region or regions 160 may be defined on an opposite side of the recessed frame region(s) 155 from the central region 150 and may directly abut the outside edge(s) of the recessed frame region(s) 155. The raised frame regions may have widths of, for example, about 1 μm. The raised frame region(s) 160 may be defined by areas where the top electrode 120 is thicker than in the central region 150 and in the recessed frame region(s) 155. The top electrode 120 may have the same thickness in the central region 150 and in the recessed frame region(s) 155 but a greater thickness in the raised frame region(s) 160. The top electrode 120 may be between about 50 nm and about 500 nm thicker in the raised frame region(s) 160 than in the central region 150 and/or in the recessed frame region(s) 155. In some embodiments the thickness of the top electrode in the central region may be between 50 and 500 nm. In other embodiments, the top electrode 120 may have the same thickness in the central region 150, the recessed frame region(s) 155, and the raised frame region(s) 160, and the raised frame may be defined by a thicker layer of dielectric film 300 in the raised frame regions than in the central region 150 and recessed frame region(s) 155.

The recessed frame region(s) 155 and the raised frame region(s) 160 may contribute to dissipation or scattering of transverse acoustic waves generated in the FBAR 100 during operation and/or may reflect transverse waves propagating outside of the recessed frame region(s) 155 and the raised frame region(s) 160 and prevent these transverse acoustic waves from entering the central region and inducing spurious signals in the main active domain region of the FBAR. Without being bound to a particular theory, it is believed that due to the thinner layer of dielectric material 130 on top of the top electrode 120 in the recessed frame region(s) 155, the recessed frame region(s) 155 may exhibit a higher velocity of propagation of acoustic waves than the central region 150. Conversely, due to the increased thickness and mass of the top electrode 120 in the raised frame region(s) 160, the raised frame regions(s) 160 may exhibit a lower velocity of propagation of acoustic waves than the central region 150 and a lower velocity of propagation of acoustic waves than the recessed frame region(s) 155. The discontinuity in acoustic wave velocity between the recessed frame region(s) 155 and the raised frame region(s) 160 creates a barrier that scatters, suppresses, and/or reflects transverse acoustic waves.

In alternative embodiments, electrical contact to the top and bottom electrodes 120, 125 may be made by vias filled with a conductive material, for example, copper, aluminum, or some other metal or alloy, that pass through the substrate 110 and electrically connect the top and bottom electrodes 120, 125 to bond pads on the lower surface of the substrate 110 (conductive through substrate vias). The bond pads may be used to electrically connect the FBAR to a packaging substrate, for example, a printed circuit board. In the example illustrated in FIG. 1B, the lower electrode 125 includes a portion that passes through a via 142 defined in the dielectric layer 110A (a dielectric layer via) on the upper surface of the substrate 110. The bottom of this portion of the bottom electrode 125 is electrically connected to a conductive through substrate via (TSV) 144 below the dielectric layer via 142. The TSV 144 extends through the substrate 100 (and lower layers 110A, 110B, when present) and electrically connects to a bond pad 146 on the lower surface of the substrate. The dielectric layer via, TSV, and bond pad for the top electrode 120 are not illustrated in FIG. 1B, but may be formed in a similar manner as the corresponding features illustrated for the bottom electrode 125.

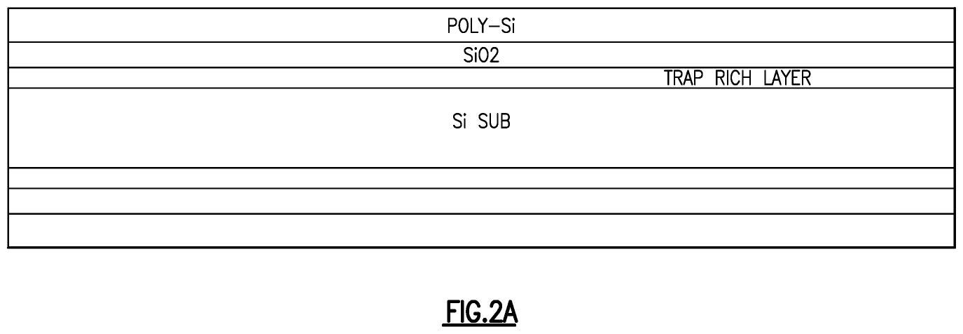

In some FBAR manufacturing processes, the dielectric layer via (or vias) 142 for the lower (and/or upper) electrodes are formed early in what may be referred to as the “front end” of the manufacturing process. For example, as illustrated in FIG. 2A, a manufacturing process for a FBAR may begin by growing, depositing, or otherwise forming layers of trap rich silicon (or polysilicon), silicon dioxide, and polysilicon on a base substrate, for example, a silicon wafer. The upper layer of polysilicon is then patterned by lithographic pattern definition and etch, using methods known in the art, to form polysilicon islands as illustrated in FIG. 2B. The polysilicon islands are sacrificial material that will be later be used to define the cavities 135 of the FBARs and then etched away, for example, after depositing the electrode and piezoelectric material layers on top of the polysilicon islands. After defining the polysilicon islands the dielectric layer vias 142 are photolithographically patterned and etched through the upper silicon dioxide layer, optionally after depositing a thin layer of silicon dioxide on the polysilicon islands as illustrated in FIG. 2C. The Ru and Ti layers (or other metal layers) forming the lower electrode are then deposited in the dielectric layer vias 142 and on the polysilicon islands as illustrated in FIG. 2D. The process then continues to form the remaining layers of the FBAR. The front end of the process ends with the FBAR formed substantially as illustrated in FIG. 1B, but without the TSV 144 or bond pad 146 formed. The TSV 144 and bond pad 146 are formed in what is referred to as a “back end” of the FBAR manufacturing process.

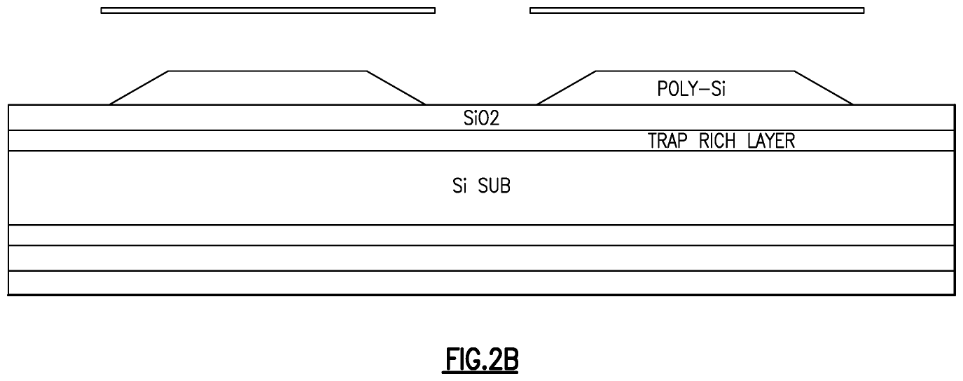

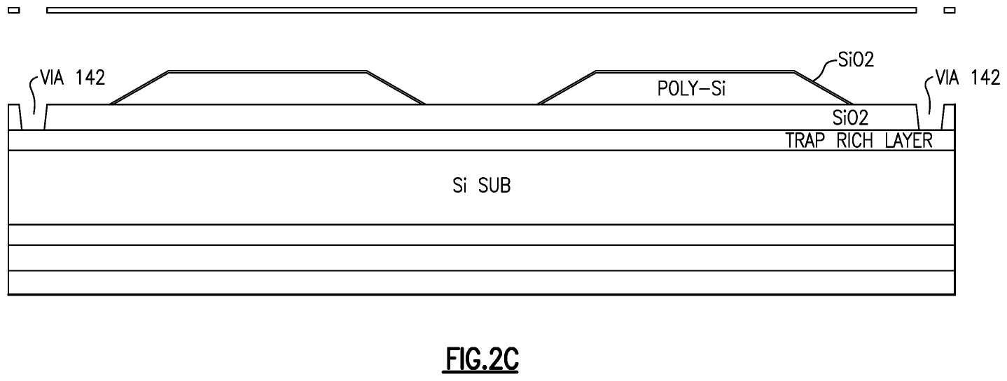

In some embodiments, multiple BAWs as disclosed herein may be combined into a filter, for example, an RF ladder filter schematically illustrated in FIG. 3A and including a plurality of series resonators R1, R3, R5, R7, and R9, and a plurality of parallel (or shunt) resonators R2, R4, R6, and R8. As shown, the plurality of series resonators R1, R3, R5, R7, and R9 are connected in series between the input and the output of the RF ladder filter, and the plurality of parallel resonators R2, R4, R6, and R8 are respectively connected between series resonators and ground in a shunt configuration.

In some examples, a ladder filter may be formed with one or more series or shunt resonators cascaded, for example, with more than one resonator connected in series in place of any one of the resonators R1-R9 of FIG. 3A or with one or more of the series or shunt resonators split, for example, with more than one resonator connected in parallel in place of any one of the resonators R1-R9 of FIG. 3A. One example of such a ladder filter with both cascaded and split series and shunt resonators is illustrated in simplified view in FIG. 3B. In the ladder filter of FIG. 3B series resonators S1a and S1b are connected in series and are thus considered cascaded. Similarly shunt resonators P2a and P2b are connected in series and are thus considered cascaded. The combination of cascaded series resonators S1a and S1b are connected in parallel with the combination of cascaded series resonators S1c and S1d. These two combinations of resonators are thus considered arranged in a split configuration. Shunt resonators P1a and P1b are connected in parallel and thus considered connected in a split configuration. The provision of cascaded (series connected) or split (parallel connected) resonator elements may, for example, improve power handling capabilities of the ladder filter and/or shape the passband of the ladder filter in a manner desired for a particular implementation.

Other filter structures and other circuit structures known in the art that may include BAW devices or resonators, for example, duplexers, notch filters, baluns, etc., may also be formed including examples of BAW resonators as disclosed herein.

It has been observed that for ladder filters in which series resonators are split or in which shunt resonators are cascaded and the resonators are formed from FBARs with the dielectric material via 142 formed in the front end of the manufacturing process as described above, discontinuities or spikes may sometimes occur in the passband of the filter near the resonance frequency of the series resonators and/or near the antiresonance frequency of the shunt resonators. Without wishing to be bound to any particular theory, it is believed that forming the dielectric material via 142 in the front end of the manufacturing process may damage the upper surface of the dielectric layer 110A, polysilicon islands, or upper surface of the exposed portion of the trap rich layer 110B, or possibly leave residue which results in unwanted shifts in the resonance or antiresonance frequencies of the FBARs formed by this method.

Accordingly, a method of manufacturing FBARs has been developed in which the dielectric material via 142 is formed in the back end of the manufacturing process after forming the electrodes, piezoelectric layer(s), and passivation layers of the FBAR structure.

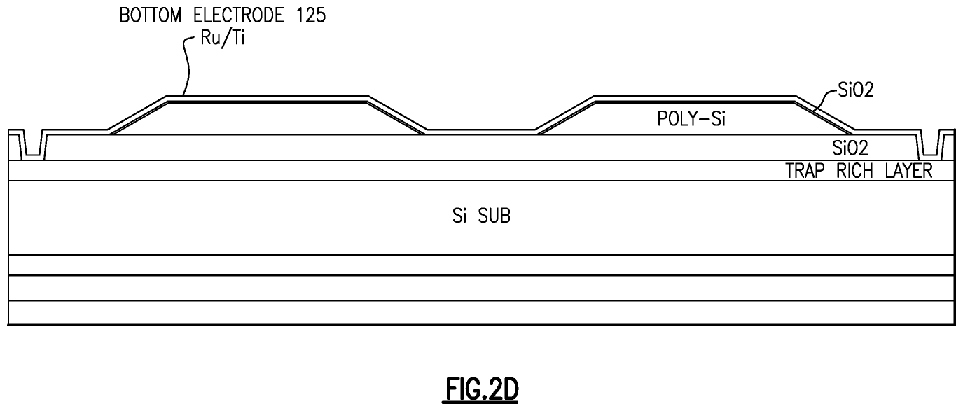

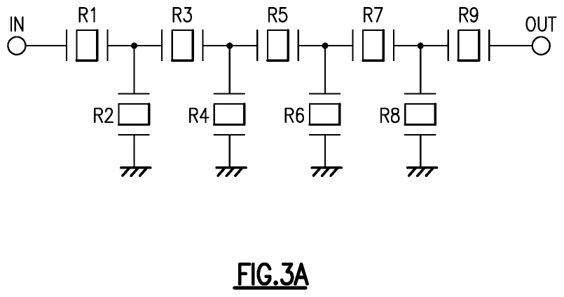

In methods such as described above in which the dielectric material via 142 is formed in the front end of the manufacturing process, the back end of the manufacturing process includes anisotropically etching a hole for the TSV 144 up from the bottom of the substrate 110 and through the trap rich or polysilicon layer 110B, and through a Ti seed layer optionally used in the formation of the bottom electrode, and then filling the hole with a metal to form the TSV 144. The resulting structure is illustrated in FIG. 4A. FIG. 4A can be considered an expanded view of the portion of the region where the TSV 144 and lower electrode 125 meet in FIG. 1B. As illustrated, the TSV 144 and lower electrode 125 are connected at a plane defined at an interface between the dielectric layer 110A and trap rich or polysilicon layer 110B (or between the dielectric layer 110A and Ti seed layer, if used). The connection between the TSV 144 and lower electrode 125 may be considered “substantially coplanar” with the interface between the dielectric layer 110A and trap rich or polysilicon layer 110B even if the Ti seed layer is present as illustrated in FIG. 4A. The connection between the TSV 144 and lower electrode 125 is proximate the lower side of the dielectric layer 110A and distal from the upper side of the dielectric layer 110A. In some embodiments the sidewalls of the dielectric material via 142 may be angled, especially if the dielectric material via 142 was formed with an isotropic plasma etch in the front end of the process. FIG. 4B illustrates the resultant structure in a process in which an AlN layer was used as a seed layer for forming the bottom electrode 125 and was not deposited over the area in which the dielectric material via 142 was formed. In this structure, the TSV 144 and lower electrode 125 are connected at a plane defined by an interface between the dielectric layer 110A and trap rich or polysilicon layer 110B. In each version of the process in which the dielectric material via 142 is formed in the process front end as illustrated in FIGS. 4A and 4B, the width of the dielectric material via 142 is greater than the width of the TSV 144.

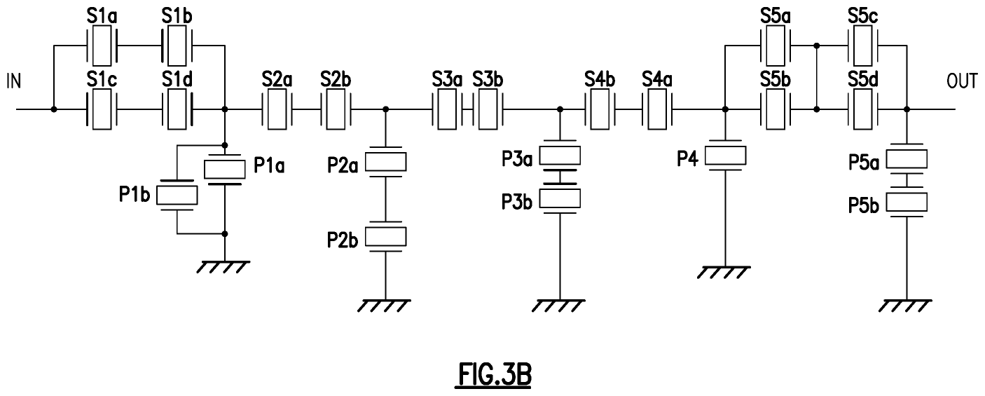

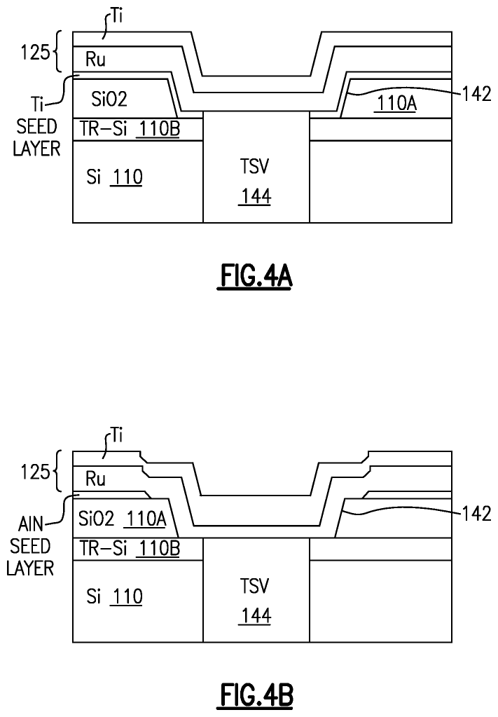

One example of a structure including the joined TSV 144 and lower electrode 125 in which the dielectric material via 142 is not formed in the front end of the process, but rather in the back end of the manufacturing process, is shown in FIG. 5A. To form the structure shown in FIG. 5A, a hole for the TSV 144 is anisotropicaly etched up from the bottom of the substrate 110 and through the trap rich or polysilicon layer 110B and the dielectric layer 110A. The TSV 144 and lower electrode 125 are connected at a plane defined by the top surface of the dielectric layer 110A (or within the Ti seed layer above the top of the dielectric layer 110A) rather than at or proximate the bottom of the dielectric layer 110A, depending on whether the bottom electrode Ti seed layer is used. The connection between the TSV 144 and lower electrode 125 may be considered “substantially coplanar” with the interface between the dielectric layer 110A and lower electrode 125 even if the Ti seed layer is present as illustrated in FIG. 5A. In contrast to the structures shown in FIGS. 4A and 4B, the width of the dielectric material via 142 is the same as the width of the TSV 144.

In an alternative method, an AlN layer may be used as a seed layer for the bottom electrode 125 in a similar manner as in the structure shown in FIG. 4B. In such a method, if the dielectric material via 142 is not formed in the front end of the process, but rather, the dielectric layer 110A is etched through in the back end of the process to form the TSV 144, the structure illustrated in FIG. 5B may result. As can be seen, the TSV 144 and bottom electrode 125 meet at the plane defined by the top surface of the dielectric layer 110A in an area in which the AlN seed layer is not present. Again, the width of the silicon dioxide via 142 is the same as the width of the TSV 144.

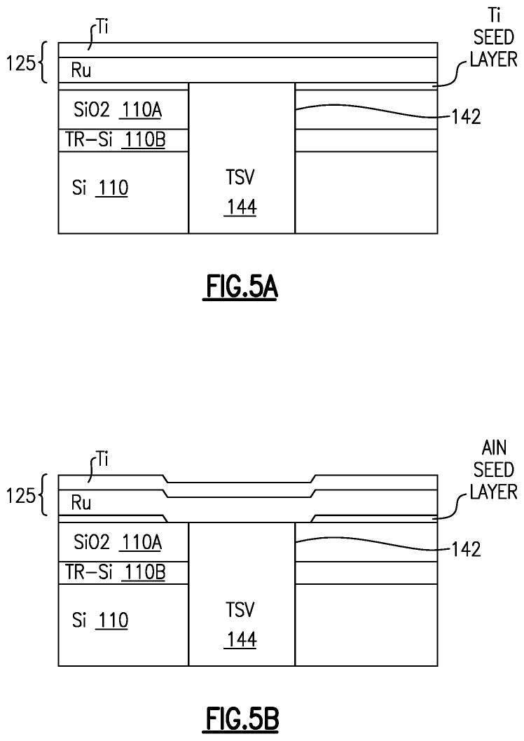

The acoustic wave devices discussed herein can be implemented in a variety of packaged modules. Some example packaged modules will now be discussed in which any suitable principles and advantages of the packaged acoustic wave devices discussed herein can be implemented. FIGS. 6, 7, and 8 are schematic block diagrams of illustrative packaged modules and devices according to certain embodiments.

As discussed above, embodiments of the disclosed BAWs can be configured as or used in filters, for example. In turn, a BAW filter using one or more BAW elements may be incorporated into and packaged as a module that may ultimately be used in an electronic device, such as a wireless communications device, for example. FIG. 6 is a block diagram illustrating one example of a module 400 including a BAW filter 410. The BAW filter 410 may be implemented on one or more die(s) 420 including one or more connection pads 422. For example, the BAW filter 410 may include a connection pad 422 that corresponds to an input contact for the BAW filter and another connection pad 422 that corresponds to an output contact for the BAW filter. The packaged module 400 includes a packaging substrate 430 that is configured to receive a plurality of components, including the die 420. A plurality of connection pads 432 can be disposed on the packaging substrate 430, and the various connection pads 422 of the BAW filter die 420 can be connected to the connection pads 432 on the packaging substrate 430 via electrical connectors 434, which can be solder bumps or wirebonds, for example, to allow for passing of various signals to and from the BAW filter 410. The module 400 may optionally further include other circuitry die 440, such as, for example, one or more additional filter(s), amplifiers, pre-filters, modulators, demodulators, down converters, and the like, as would be known to one of skill in the art of semiconductor fabrication in view of the disclosure herein. In some embodiments, the module 400 can also include one or more packaging structures to, for example, provide protection and facilitate easier handling of the module 400. Such a packaging structure can include an overmold formed over the packaging substrate 430 and dimensioned to substantially encapsulate the various circuits and components thereon.

Various examples and embodiments of the BAW filter 410 can be used in a wide variety of electronic devices. For example, the BAW filter 410 can be used in an antenna duplexer, which itself can be incorporated into a variety of electronic devices, such as RF front-end modules and communication devices.

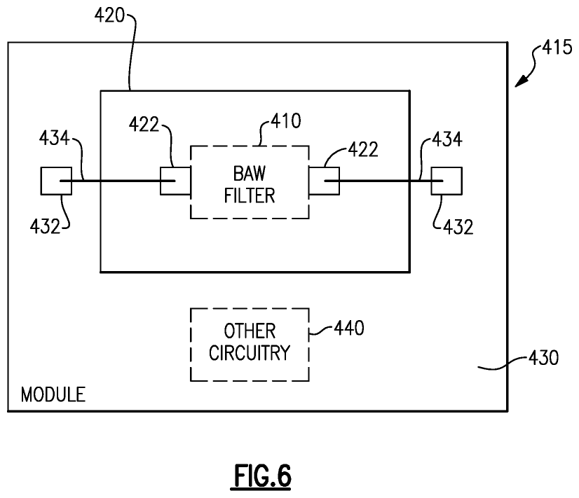

Referring to FIG. 7, there is illustrated a block diagram of one example of a front-end module 500, which may be used in an electronic device such as a wireless communications device (e.g., a mobile phone) for example. The front-end module 500 includes an antenna duplexer 510 having a common node 502, an input node 504, and an output node 506. An antenna 610 is connected to the common node 502.

The antenna duplexer 510 may include one or more transmission filters 512 connected between the input node 504 and the common node 502, and one or more reception filters 514 connected between the common node 502 and the output node 506. The passband(s) of the transmission filter(s) are different from the passband(s) of the reception filter(s). Examples of the BAW filter 410 can be used to form the transmission filter(s) 512 and/or the reception filter(s) 514. An inductor or other matching component 520 may be connected at the common node 502.

The front-end module 500 further includes a transmitter circuit 532 connected to the input node 504 of the duplexer 510 and a receiver circuit 534 connected to the output node 506 of the duplexer 510. The transmitter circuit 532 can generate signals for transmission via the antenna 610, and the receiver circuit 534 can receive and process signals received via the antenna 610. In some embodiments, the receiver and transmitter circuits are implemented as separate components, as shown in FIG. 7, however in other embodiments these components may be integrated into a common transceiver circuit or module. As will be appreciated by those skilled in the art, the front-end module 500 may include other components that are not illustrated in FIG. 7 including, but not limited to, switches, electromagnetic couplers, amplifiers, processors, and the like.

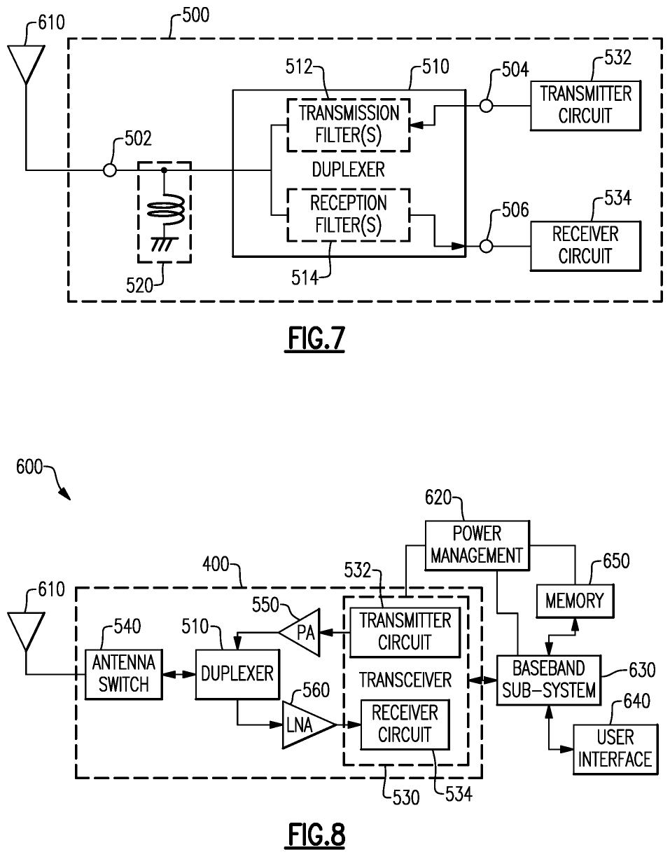

FIG. 8 is a block diagram of one example of a wireless device 600 including the antenna duplexer 510 shown in FIG. 7. The wireless device 600 can be a cellular phone, smart phone, tablet, modem, communication network or any other portable or non-portable device configured for voice or data communication. The wireless device 600 can receive and transmit signals from the antenna 610. The wireless device includes an embodiment of a front-end module 500 similar to that discussed above with reference to FIG. 7. The front-end module 500 includes the duplexer 510, as discussed above. In the example shown in FIG. 8 the front-end module 500 further includes an antenna switch 540, which can be configured to switch between different frequency bands or modes, such as transmit and receive modes, for example. In the example illustrated in FIG. 8, the antenna switch 540 is positioned between the duplexer 510 and the antenna 610; however, in other examples the duplexer 510 can be positioned between the antenna switch 540 and the antenna 610. In other examples the antenna switch 540 and the duplexer 510 can be integrated into a single component.

The front-end module 500 includes a transceiver 530 that is configured to generate signals for transmission or to process received signals. The transceiver 530 can include the transmitter circuit 532, which can be connected to the input node 504 of the duplexer 510, and the receiver circuit 534, which can be connected to the output node 506 of the duplexer 510, as shown in the example of FIG. 7.

Signals generated for transmission by the transmitter circuit 532 are received by a power amplifier (PA) module 550, which amplifies the generated signals from the transceiver 530. The power amplifier module 550 can include one or more power amplifiers. The power amplifier module 550 can be used to amplify a wide variety of RF or other frequency-band transmission signals. For example, the power amplifier module 550 can receive an enable signal that can be used to pulse the output of the power amplifier to aid in transmitting a wireless local area network (WLAN) signal or any other suitable pulsed signal. The power amplifier module 550 can be configured to amplify any of a variety of types of signal, including, for example, a Global System for Mobile (GSM) signal, a code division multiple access (CDMA) signal, a W-CDMA signal, a Long-Term Evolution (LTE) signal, or an EDGE signal. In certain embodiments, the power amplifier module 550 and associated components including switches and the like can be fabricated on gallium arsenide (GaAs) substrates using, for example, high-electron mobility transistors (pHEMT) or insulated-gate bipolar transistors (BiFET), or on a Silicon substrate using complementary metal-oxide semiconductor (CMOS) field effect transistors.

Still referring to FIG. 8, the front-end module 500 may further include a low noise amplifier module 560, which amplifies received signals from the antenna 610 and provides the amplified signals to the receiver circuit 534 of the transceiver 530.

The wireless device 600 of FIG. 8 further includes a power management sub-system 620 that is connected to the transceiver 530 and manages the power for the operation of the wireless device 600. The power management system 620 can also control the operation of a baseband sub-system 630 and various other components of the wireless device 600. The power management system 620 can include, or can be connected to, a battery (not shown) that supplies power for the various components of the wireless device 600. The power management system 620 can further include one or more processors or controllers that can control the transmission of signals, for example. In one embodiment, the baseband sub-system 630 is connected to a user interface 640 to facilitate various input and output of voice and/or data provided to and received from the user. The baseband sub-system 630 can also be connected to memory 650 that is configured to store data and/or instructions to facilitate the operation of the wireless device, and/or to provide storage of information for the user. Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a range from about 30 kHz to 300 GHz, such as in a range from about 450 MHz to 6 GHz.

Aspects of this disclosure can be implemented in various electronic devices. Examples of the electronic devices can include, but are not limited to, consumer electronic products, parts of the consumer electronic products such as packaged radio frequency modules, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A method of fabricating an acoustic wave resonator, the method comprising:
forming a dielectric layer on an upper surface of a substrate;
forming a lower electrode on an upper surface of the dielectric layer;
forming a layer of piezoelectric material on an upper surface of the lower electrode;
forming a dielectric material layer via in the dielectric layer subsequent to forming the lower electrode and the layer of piezoelectric material; and
forming a conductive through substrate via passing through the substrate and the dielectric material layer via and contacting a lower surface of the lower electrode.

2. The method of claim 1 wherein the dielectric material layer via is formed in a back end portion of a manufacturing process for the acoustic wave resonator.

3. The method of claim 1 further comprising:
forming an upper electrode on an upper surface of the layer of piezoelectric material;
forming a second dielectric material layer via in the dielectric layer subsequent to forming the upper electrode; and
forming a second conductive through substrate via passing through the substrate and the dielectric material layer via and contacting a lower surface of the upper electrode.

4. The method of claim 1 further comprising forming an adhesion layer on the upper surface of the dielectric layer prior to forming the lower electrode on the upper surface of the dielectric layer.

5. The method of claim 4 wherein contacting the lower surface of the lower electrode with the conductive through substrate via includes contacting the lower surface of the lower electrode with the conductive through substrate via at a position substantially coplanar with an upper surface of the dielectric layer.

6. The method of claim 4 wherein contacting the lower surface of the lower electrode with the conductive through substrate via includes contacting the lower surface of the lower electrode with the conductive through substrate via at a position proximate an upper surface of the dielectric layer.

7. The method of claim 4 wherein contacting the lower surface of the lower electrode with the conductive through substrate via includes contacting the lower surface of the lower electrode with the conductive through substrate via at a position coplanar with an upper surface of the adhesion layer.

8. The method of claim 1 wherein contacting the lower surface of the lower electrode with the conductive through substrate via includes contacting the lower surface of the lower electrode with the conductive through substrate via at a position coplanar with an upper surface of the dielectric layer.

9. The method of claim 1 wherein the conductive through substrate via is formed with a same width as a width of the dielectric material layer via.

10. The method of claim 1 wherein contacting the lower surface of the lower electrode with the conductive through substrate via includes contacting the lower surface of the lower electrode with the conductive through substrate via at a position distal from a lower surface of the dielectric layer.

11. The method of claim 1 wherein the dielectric material layer via is not formed in a front end portion of a manufacturing process for the acoustic wave resonator.

12. A bulk acoustic wave resonator comprising:
a dielectric layer disposed on an upper surface of a substrate;
a lower electrode disposed on an upper surface of the dielectric layer;
a layer of piezoelectric material disposed on an upper surface of the lower electrode;
a dielectric material layer via defined in the dielectric layer; and
a conductive through substrate via passing through the substrate and the dielectric material layer via and contacting a lower surface of the lower electrode at a position proximate an upper surface of the dielectric material layer.

13. The bulk acoustic wave resonator of claim 12 further comprising:
an upper electrode disposed on an upper surface of the layer of piezoelectric material;
a second dielectric material layer via defined in the dielectric layer; and
a second conductive through substrate via passing through the substrate and the dielectric material layer via and contacting a lower surface of the upper electrode a position proximate an upper surface of the dielectric material layer.

14. The bulk acoustic wave resonator of claim 12 further comprising an adhesion layer disposed between the upper surface of the dielectric layer and the lower electrode.

15. The bulk acoustic wave resonator of claim 14 the lower surface of the lower electrode contacts the conductive through substrate via at a position substantially coplanar with an upper surface of the dielectric layer.

16. The bulk acoustic wave resonator of claim 14 wherein the lower surface of the lower electrode contacts the conductive through substrate via at a position proximate an upper surface of the dielectric layer.

17. The bulk acoustic wave resonator of claim 14 wherein the lower surface of the lower electrode contacts the conductive through substrate at a position coplanar with an upper surface of the adhesion layer.

18. The bulk acoustic wave resonator of claim 12 wherein the lower surface of the lower electrode contacts the conductive through substrate via at a position coplanar with an upper surface of the dielectric layer.

19. The bulk acoustic wave resonator of claim 12 wherein the conductive through substrate via is has a same width as a width of the dielectric material layer via.

20. The bulk acoustic wave resonator of claim 12 wherein the lower surface of the lower electrode contacts the conductive through substrate via at a position distal from a lower surface of the dielectric layer.
